(19) United States
(12) Patent Application Publication
(10) Pub. No.: US 2024/0418600 A1
(43) Pub. Date: Dec. 19, 2024

(54) METHOD FOR THE GEOMETRIC CHARACTERISATION OF OPTICAL LENSES

(71) Applicant: FOGALE NANOTECH, Nîmes (FR)

(72) Inventors: Eric LEGROS, Nîmes (FR); Sylvain PETITGRAND, Caissargues (FR); Jérôme PORQUE, La Grande Motte (FR)

(21) Appl. No.: 18/706,079

(22) PCT Filed: Nov. 7, 2022
(86) PCT No.: PCT/EP2022/082252

§ 371 Date: Apr. 30, 2024

(30) Foreign Application Priority Data
Nov. 19, 2021 (FR) FR2112263

(51) Int. Cl. G01M 11/02; G06F 30/17

(52) U.S. Cl. CPC G01M 11/0271; G06F 30/17

(57) ABSTRACT

A method for optical characterization of a target optical objective to be manufactured by stacking several optical elements, the method including a characterization phase of the following steps:
determining an assembly including, for each element at least one characteristic parameter of the optical element; and
providing, as a function of the assembly set, an estimated geometric set, including data relating to at least one geometric parameter of at least one optical interface of the stack, by a geometric characterization model trained beforehand with a database, called training database, of training sets constituted based on optical objectives with architecture identical to that of the target objective, and further relates to
   a device for geometric characterization of optical objectives implementing such a geometric characterization method and to a method and a system for the manufacture of optical objectives implementing such a characterization method or device.

The present invention relates to a method for geometric characterization of an optical objective, in particular before the manufacture thereof or during the manufacture thereof, so as to estimate at least one indicator relating to the quality of the optical objective once assembled. It also relates to a device for geometric characterization implementing such a method. It relates moreover to a method and a system for the manufacture of optical objectives implementing such a geometric characterization method or device.

The field of the invention is the field of qualitative characterization of optical objectives, in particular before or during the manufacture thereof.

### STATE OF THE ART

An optical objective is constituted by a stack of optical elements, in a barrel, in a given order and according to a stacking direction, also called the axis Z. The optical elements of an optical objective, also called objective hereinafter, can be optical lenses that are convergent, divergent, aspherical, or optionally other complex shapes, or a sleeve, also called “spacer” or “SOMA®)”, or also beam splitters or filters.

Optical objectives are used in various appliances, such as for example cameras for video and still photography, smartphones, etc. for imaging a scene, or as a light source, to project patterns, to light a scene, etc.

Once assembled, the optical objective is tested to determine an item of performance data relating to the functioning of said objective, mainly to validate or not the quality of said objective. Different techniques currently exist for testing an optical objective after the manufacture thereof, such as for example measurement of the MTF (“modulation transfer function”) value.

One of the limitations of the current characterization techniques is that they require manufacture of the optical objective to be completed before being able to characterize the optical objective. Thus, when the optical objective is deemed unsatisfactory, it is often scrapped, which constitutes a loss of time and resources.

As a result, the current techniques do not make it possible to improve the efficiency of production of optical objectives since these techniques are involved at a very late stage of the manufacture of the optical objective.

An aim of the present invention is to overcome at least one of the aforementioned drawbacks.

Another aim of the invention is to propose a solution for characterization of optical objectives that is less time-consuming and more efficient.

Another aim of the invention is to propose a solution for characterization of optical objectives making it possible to improve the development of the methods for manufacturing optical objectives and their components.

Another aim of the invention is to propose a solution for characterization of optical objectives making it possible to improve the efficiency of production of optical objectives.

### DISCLOSURE OF THE INVENTION

The invention proposes to achieve at least one of the aforementioned aims by a method for geometric characterization of a target optical objective to be manufactured by stacking several optical elements, said method comprising a characterization phase comprising the following steps:
determining a set, called assembly set, comprising, for at least one optical element, a set, called individual set, comprising at least one parameter characteristic of said optical element; and
providing, as a function of said assembly set, a data set, called estimated geometric set, comprising data relating to at least one geometric parameter of at least one optical interface of said stack, by a geometric characterization model trained beforehand with a database, called training database, of training sets constituted with optical objectives with architecture identical to that of said target objective.

Thus, the method according to the invention makes it possible to provide, by estimation, at least one geometric parameter relating to at least one, and in particular each, optical interface of the target optical objective that will be obtained as a function of at least one characteristic parameter of at least one, in particular each, optical element composing said target optical objective. In other words, with the method according to the invention, it is possible to obtain an estimated indicator relating to the optical objective before the manufacture thereof. This estimated indicator, provided by the method according to the invention, can be used to estimate the quality, or the functional performance, of the target objective once manufactured, for example by comparison with a threshold, or a range of values, in order to determine if the target optical objective, once manufactured, would perform well or not. Thus, it is possible to have an opinion on the performance of the target objective even before beginning the manufacture thereof, or during the manufacture thereof. The method according to the invention makes it possible, as a result, to increase the efficiency of manufacture of optical objectives, this efficiency being defined as being the number of satisfactory optical objectives divided by the total number of optical objectives manufactured. The method according to the invention also makes it possible to reduce the losses of time and cost associated with the production of an optical objective the performance of which would not be satisfactory.

In addition, the characterization of an optical objective based on the parameters of the optical elements of which it is composed is quicker and less time-consuming, compared with the current characterization techniques, such as characterization techniques by measurement of MTF values.

Above all, the invention makes it possible to give an indication of the quality of the optical objective on the basis of the optical elements of which it is composed. Thus, it is possible to adjust the composition of the optical objective, for example by replacing an optical element with another or by modifying the arrangement of an optical system, at the very moment of design of the optical objective. In fact, the characteristics of each optical component of the objective can be known before beginning the manufacture of the optical objective, or even at the moment of design of the optical objective, or even at the moment of design of each optical element. Thus, the invention makes it possible to obtain an indication of the quality of the optical objective very early in the manufacturing process.

At least one item of data of the estimated geometric set, and in particular the estimated geometric set, can be compared with at least one predetermined threshold value, or range of values, to obtain an indication of the functional quality or the functional performance of the target optical objective.

This indication can be a classification of the target optical objective such as “good” or “not good”. Alternatively, or in addition, this indication can be any other type of data.

The optical elements composing an optical objective are stacked according to a stacking direction, also called axis Z hereinafter, or also the axis of the optical objective. The plane perpendicular to the axis Z, i.e. the plane along which each optical element extends, is called the plane X-Y hereinafter.

In the present application, the geometric characterization model, also called characterization model hereinafter, provides data relating to the geometry of the optical interfaces of the objective, also called “geometric parameter” of the optical interface, in the present application.

By “geometric parameter of an optical interface” is meant, for example, and without loss of generality:
a position of the optical interface within the objective, in the axis Z;
a position of an APEX of the optical interface, in particular in the plane X-Y and/or
a position of an APEX of the optical interface, in particular according to the axis Z,
an inclination (TIP and/or TILT) of said optical interface with respect to the axis Z,
a decentration of an optical interface, or of an optical element, with respect to the axis Z, in the plane X-Y.

Two optical objectives have an identical architecture when each of these optical objectives comprises by design identical optical elements that are stacked by design in identical fashion.

In the present application, by “buried optical interface” of an optical objective is meant an interface within the optical objective which is only visible, or accessible, via at least one other optical interface of the objective. The at least one other optical interface through which the buried interface is visible can be an optical interface of one and the same optical element, or an optical interface of an optical element other than the buried interface.

The estimated geometric set can comprise data relating to at least one geometric parameter of at least one buried interface of said stack.

The estimated geometric set can comprise data relating to at least one geometric parameter of at least one non-buried interface of said stack.

According to embodiments, at least one individual set, denoted JI hereinafter, of an optical element can comprise any combination of at least one of the following parameters:
at least one optical parameter of said optical element;
at least one geometric parameter of said optical element;
at least one manufacturing parameter of said optical element.

For example, at least one optical parameter of an optical element can be one of the following optical parameters:
a refractive index,
an Abbe number,
etc.

For example, at least one geometric parameter of an optical element can be one of the following geometric parameters:
a geometric shape of one, in particular of each, optical interface of the optical element,
a centre of curvature of one, in particular of each, optical interface of the optical element,
a position of an apex of one, in particular of each, optical interface of the optical element,
at least one thickness of said optical element along the circumference of said optical element,
an internal diameter, and/or an external diameter, of said optical element,
a concentricity, or an eccentricity, of the optical interfaces of the optical element,
a surface roughness of at least one, in particular of each, interface of the optical element,
etc.

For example, at least one manufacturing parameter of an optical element can be at least one of the following manufacturing parameters:
a moulding temperature,
a moulding pressure,
a moulding time,
a polymer used for the moulding,
etc.

At least one parameter of an optical element can be provided by a supplier, or a manufacturer.

Such a parameter can form part of the specifications of the optical element at the moment of its design, or measured during, or after, the manufacture of the optical element.

Such a parameter can be any one of the parameters listed above.

Alternatively, or in addition, at least one parameter of an optical element can be calculated based on a digital modelling of said element.

In fact, different software tools exist for simulation and design, such as for example “OSLO®” or “Zemax®”, making it possible to digitally model an optical element in order to determine at least one characteristic of said optical element, by simulation, based on the digital modelling thereof.

Such a parameter can be any one of the parameters listed above.

Alternatively, or in addition, at least one parameter of an optical element can be measured by a measurement device.

For example, at least one geometric parameter can be obtained by an optical profilometry appliance or a mechanical profilometry appliance. In fact, such an appliance makes it possible to detect the shape of the optical element, the thickness of the optical element, the position of the APEX, the roughness, etc.

For example, at least one geometric parameter can be obtained by an optical interferometry appliance in point mode or in full-field mode. Such a parameter can be any one of the parameters listed above.

According to embodiments, the estimated geometric set can comprise estimated data of a part, or all, of the raw optical measurement values obtained from the stack of optical elements of said target optical objective.

For example, the geometric set can comprise estimated confocal measurement data, or estimated optical interferometry measurement data, executed on the optical element stack. In other words, the estimated geometric set can comprise estimated optical measurement data, without carrying out these optical measurements. Thus, the method according to the invention makes it possible firstly to facilitate and accelerate the development phases of the methods for the manufacture of the optical objectives and secondly to improve the monitoring and the implementation of the production in a second instance.

The geometric set can in particular comprise estimated optical measurement data produced only from one face, or one side, of the stack of optical elements without having to turn said stack over. Thus, the estimated geometric set comprises estimated data relating to at least one, and in particular to each, optical interface of the optical objective, including each buried optical interface, of the stack of optical elements.

According to embodiments, the estimated geometric set can comprise estimated data of at least one confocal measurement carried out on the stack of optical elements of the target optical objective, preferably from one face of said stack.

Conventionally, a confocal measurement is carried out with an appliance which comprises a first opening (orifice) imaged on the surface to be measured via a focusing lens. This opening is lit by a light beam originating from a light source and which is then directed towards the surface to be measured. When the beam is reflected by a surface, it is redirected towards the focusing lens then towards a second lens placed in front of a detection element and so as to be the conjugate image of the illuminated point on the measured surface. The advantage of such a configuration is the reduction of the depth of field and thus of being able to more easily distinguish objects (or surfaces) one under another. To carry out the detection, the confocal measurement system is displaced relatively with respect to the measured object. A maximum intensity is detected on the detection element when a surface enters the focal point defined by the focusing lens. A particular configuration of a confocal measurement system uses a chromatic lens for focusing and imaging a beam originating from a polychromatic source. The different wavelengths thus define different focal points along the optical axis of the lens. Detection with a spectrometer of the reflected light makes it possible to recognize the reflected wavelength and to deduce therefrom an item of height (or distance) information between the lens and the measured surface. Such a configuration makes it possible to eliminate or reduce the displacement of the confocal measurement system. In particular, when the confocal measurement system is displaced along a plane perpendicular to the axis of illumination of the surface to be measured, items of topography information of a surface can be obtained.

According to embodiments, the estimated geometric set can comprise estimated data of at least one optical interferometry measurement carried out on the stack of optical elements of the target optical objective, preferably from one face of said stack.

Conventionally, an optical interferometry measurement is carried out with an optical interferometry appliance comprising an emitting low-coherence light source. This light source emits, in the direction of stacking of optical elements, and more particularly according to the axis Z, a light beam, called measurement beam. The measurement beam illuminates the stack of optical elements at a measurement point that is more or less wide according to the focusing in the plane X-Y, and then travels through the stack of optical elements, in particular in the direction of stacking, and passes through each optical interface in turn. At each optical interface, a part of the beam is reflected, and constitutes a reflected beam. This reflected beam is then captured by a sensor located on the same side as the emission source, and is characterized by optical interferometry with a reference beam also originating from the light source. By “coherence area” is meant the area in which interferences between the measurement beam and the reference beam can form on the sensor. The coherence area can be displaced by varying the difference in the length of the optical path between the two beams, for example by modifying the optical length of one of the beams or of both. The optical interferometry appliance makes it possible to detect an interference signal selectively for each interface at the level of which the coherence area is positioned, i.e. for each surface located in the coherence area. Preferably, the coherence length of the light source is adjusted so as to be shorter than a minimum optical distance between two adjacent interfaces of the optical element. Thus, for each measurement, a single interface is located in the coherence area, and an acquired interference signal therefore comprises only the contribution of a single interface, or only originates from a single interface. The interference measurements are performed according to a field of view determined by the measurement means of the interferometric appliance.

According to an embodiment, the interferometric appliance can operate in point mode by being configured to detect a point interference signal at a point of the field of view or in a point detector. The estimated geometric set can be, or can comprise, the interference signal or interferogram that is an intensity signal, function of the displacement of the coherence area along the axis z. The interference signal can, for example, be seen as a succession of interference rays associated with each optical interface.

Alternatively or in addition, the interferometric appliance can comprise an interferometric sensor, called full-field interferometric sensor, configured to detect a full-field interference signal in a field of view and represented, for example in the form of a 2D image (interference image) by virtue of the detection element.

An interface to be measured can thus be imaged according to the field of view in a single measurement or by scanning a beam.

In a particular example of implementation, a measurement signal can be formed by a point interference signal associated with a pixel of the detection element the intensity of which is detected according to the displacement along Z of the coherence area.

According to an example, the interferometric appliance can comprise an interferometric sensor with a Michelson interferometer. According to another example, the interferometric appliance can comprise an interferometric sensor with a Mach-Zehnder interferometer.

According to embodiments, a point mode interferometric appliance and a full-field interferometric appliance can be combined.

According to embodiments, the estimated geometric set can comprise estimated data of a part or all of the raw optical interferometry values obtained from the stack of optical elements of said target optical objective.

In other words, in this case, the geometric characterization model takes at input an assembly set and provides at output an estimated geometric set comprising estimated raw optical interferometry measurement data.

The estimated raw optical interferometry data can comprise, for each optical interface:
in point mode: at least one interference ray the position and the amplitude of which depend on the geometric distance at which said optical interface is located, with respect to a reference point/plane, at the measurement point. In particular, the reference point/plane is the point/plane of emission of the measurement wave, or of a known reference interface forming part of the measurement device. Thus, the position of an interference ray makes it possible to determine the distance at which the optical interface that is associated therewith is located, at the measurement point.
in full-field mode: a sequence of 2D interference signals acquired for a plurality of differences of optical paths making it possible to obtain items of shape information of the optical interfaces. These sequences can be acquired in different ways according to the analysis technique implemented. The plurality of 2D interference signals can in particular be acquired according to a phase-shifting interferometry method or according to a vertical scanning interferometry method. According to another embodiment that is in no way limitative, the interference signal can be processed by a digital holography calculation method. Typically, the 2D interference signals include an item of amplitude information and an item of phase information. Images associated with these items of amplitude information and images associated with these items of phase information can be constructed based on the interference signals.

For example, the estimated geometric set can comprise an estimation of the measured interference signal.

For example, the estimated geometric set can comprise estimated raw data representing, for at least one interference ray, the position and optionally the amplitude of said interference ray.

According to another example, the estimated geometric set can comprise estimated raw data representing the amplitude image and/or the phase image associated with an interference image.

An example of raw data is given hereinafter with reference to FIG. 3b for an example of point mode interferometry and with reference to FIGS. 3c-3f for an example of full-field mode interferometry.

According to embodiments, the estimated geometric set can comprise an estimated value of at least one geometric parameter of an optical interface of the target objective.

For example, the estimated geometric set can comprise, for at least one optical interface, or an optical element, of the stack:
at least one estimated position value of an optical interface, or element, of the objective;
at least one estimated thickness value of an optical element of the objective;
at least one estimated decentration value of at least one optical interface, or element, with respect to the axis Z, or relative to a centre position of another interface, in the plane X-Y; or
at least one estimated inclination value of at least one optical interface, or element, with respect to the axis Z, or relative to the inclination of another interface;
at least one estimated topography or shape profile value of at least one interface, for example with respect to a reference plane or axis to deduce therefrom, for example, decentration or inclination values.

The position according to the axis Z of an optical interface can be determined as being the position of an interference ray corresponding to said interface.

The thickness of an optical element, according to the axis Z, can be determined by calculating the distance between the interference rays corresponding to each of the optical interfaces of said optical element.

The position of an optical interface with respect to the axis Z can be determined by carrying out several optical interferometry measurements, in particular in a central area of the optical objective. By following, over the several measurements, the position according to the axis Z of the interference ray associated with said interface, it is possible to determine the position of the APEX of said optical interface. The position of the APEX of the optical interface makes it possible to determine the position of said interface with respect to the axis Z, in the plane X-Y, and therefore its decentration with respect to the axis Z.

In another example, the position of an interface with respect to the axis Z can be obtained, for example, by detection of an interference image of the interface in a central area of the optical objective and analysis of this image and/or analysis of the associated images of amplitudes or phases, in particular to obtain a profile of this surface and the position of the APEX of said optical interface.

The position of an optical element with respect to the axis Z can be determined as a function of the positions of the optical interfaces thereof.

The inclination of an optical interface with respect to the axis Z can be determined by carrying out several optical interferometry measurements, in particular in a peripheral area of the optical objective. By following, over the several measurements, the position in the axis Z of the interference ray associated with said interface, it is possible to determine the position of the interface according to the axis at the level of the edges thereof, which makes it possible to determine the inclination of said interface with respect to the axis Z.

The inclination of an optical element with respect to the axis Z can be determined as a function of the inclinations of the optical interfaces thereof.

It is also possible to determine each of these geometric parameters by using the amplitude of an interference ray, in addition to, or instead of, the position of the interference ray.

According to embodiments, at least one training set can comprise:
at least one assembly set, called training assembly set, obtained from an optical objective, called training optical objective, with architecture identical to the architecture of the target objective, and
at least one geometric set, called training geometric set, obtained from said training optical objective.

Of course, each training assembly set, respectively each training geometric set, comprises data of the same nature presented according to one and the same formalism as the assembly set, respectively the estimated geometric set. Consequently, all the characteristics described above with reference to the assembly set, respectively to the estimated geometric set, are applicable to the training assembly set, respectively to the training geometric set.

According to embodiments, for at least one training set, the training assembly set can be obtained, partially or wholly, by simulation.

For example, during the design phase of an optical element forming part of the stack of the optical objective, the architecture thereof can be modelled by representing the optical interfaces (particularly those of the lenses) by analytical formulations and by indicating digitally the spacing thereof. The theoretical values of the refractive index and the Abbe number of the materials involved can also be given. These theoretical values can then be input into commercially available optical design software as mentioned above, for example, to simulate characteristic parameters defining said optical element.

According to embodiments, for at least one training set, the training assembly set can be obtained, partially or wholly, by measurement.

In this case, at least one parameter of said training assembly set is measured, for example in a similar fashion to that which is described above with reference to the assembly set.

According to particularly advantageous embodiments, at least one training set can be obtained based on a training objective forming part of one and the same batch of objectives as the target objective, during the manufacture of said batch of objectives.

In other words, in this case, the training database is obtained, partially or wholly, from optical objectives forming part of the same batch as the target optical objective and which were manufactured beforehand. Thus, the characterization model is more precise and makes it possible to perform a more precise geometric characterization.

By “objectives from the same batch” is meant objectives that originate from one and the same architecture (same design) conceived so that the objectives produce a similar optical performance. Additionally, these objectives can also have common characteristics of manufacture such as originating from one and the same production line, being produced with a common machine, at similar periods, etc.

In this case, a first part of the manufactured optical objectives from one and the same batch is used to constitute a training database. In particular, for each optical objective from this first part of the batch, a training set is constituted comprising:
a training assembly set: the latter comprising at least one parameter of at least one optical element which is either measured, or provided by a supplier, or obtained by simulation; and
at least one training geometric set: the latter comprising at least one item of data relating to at least one geometric parameter of at least one, in particular each, optical interface of the stack, which is either measured, for example by a confocal measurement or by an interferometry measurement, or obtained by simulation based on a digital modelling of the optical objective in question.

Thus, the first manufactured optical objectives from a batch make it possible to constitute a training database. The latter is used to train the geometric characterization model. Once the geometric characterization model is trained, it is used to characterize the following optical objectives of said batch.

According to embodiments, for at least one training set, the training geometric set can be obtained, partially or wholly, by measurement.

In this case, said training geometric set can be measured by at least one confocal measurement, and/or at least one interferometric measurement, as described above, for providing either raw data relating to, or values of, at least one geometric parameter of at least one optical interface of the optical stack.

According to embodiments, for at least one training set, the training geometric set can be obtained, partially or wholly, by simulation.

For example, during the design phase of an optical objective, the architecture thereof can be modelled by representing the optical interfaces (particularly those of the lenses) by analytical formulations and by indicating digitally the spacing thereof. The theoretical values of the refractive index and the Abbe number of the materials involved can also be given. These theoretical values can then be input into commercially available optical design software to simulate and optimize the parameters defining the objective by calculating the theoretical functional performance. It is thus possible to calculate the optical transfer properties quite accurately by simulating the propagation of optical rays, for different points of the scene to be viewed, and the different associated points on the detection area.

Thus, the training geometric set can be obtained by simulation. Thus, the training database can be constituted, partially or wholly, by simulation, which is quicker and requires less effort and fewer resources.

According to embodiments, the geometric characterization model can comprise:
a neural network, in particular a regression neural network, and even more particularly a deep learning CNN (“convolutional neural network”) neural network. Such a neural network can, non-limitatively, comprise at least about ten layers, for example about twenty layers;
a polynomial linear regression model;
a Gaussian equation, obtained by a least squares method; or
a statistical analysis method.

According to embodiments, the method according to the invention can comprise a phase of training the geometric characterization model with the training database.

The training phase can be carried out with a training database comprising numerous training sets, denoted JE₁-JEₖ. Each training set JEᵢ comprises:
at least one training assembly set, JAAᵢ, obtained, by measurement or by simulation, based on a training optical objective the architecture of which is identical to that of the target optical objective that will be characterized by the geometric characterization model, once trained;
at least one training geometric set, JGAᵢ, obtained, by measurement or by simulation, based on said training optical objective the architecture of which is identical to that of the target optical objective that will be characterized by the geometric characterization model, once trained.

When the characterization model is a neural network, in particular a CNN, the training phase can comprise a training step which is reiterated several times.

The training step can comprise a test step. This test step comprises a step during which a training assembly set, for example JAA₁, of a training set, for example JE₁, is given at input of the neural network. The neural network gives at output an estimated training geometric set, denoted JGA₁^{e}.

During a step following the test step, an error, E₁, can be calculated between the set JGAᵢ^{e} and the training geometric set, JGA₁, of said training set JE₁. The calculated error E₁ can for example be a Euclidean distance or a cosine distance between the set JGA₁e and the set JGA₁.

The test step can be reiterated for each training set JE₁-JEₖ, so that k error values E₁-Eₖ are obtained associated respectively with each training set JE₁-JEₖ.

The training step can then comprise a step of calculating an overall error, denoted EG, for all of the training sets JE₁-JEₖ, for example by adding the k errors JE₁-JEₖ obtained.

The training step can then comprise a feedback step, during which the coefficients, or weightings, of the CNN neural network can be updated, for example by an error gradient retro-propagation algorithm.

The training step can be repeated several times until the overall error EG no longer varies during several, for example 5, successive iterations of the training step. When this is the case, the CNN neural network can be considered sufficiently trained and the training phase can be ended.

Alternatively, or in addition to what has just been described, it is possible to use a first part of the training database, for example JE₁-JEᵢ, for training the neural network and a second part of the training database, for example JEᵢ₊₁−JEₖ, to validate the training of the neural network. If the outputs of the neural network obtained are sufficiently close to the expected values, the learning can be considered acceptable. Otherwise, further training sets can be presented, or else the topology of the network can be modified (number of layers, number of neurones per layer, etc.) until a satisfactory learning is obtained.

Of course, the functional characterization model is not limited to a neural network.

According to an alternative, the functional characterization model can comprise, or can be, a correlation search method, for example by a regression method, between the training assembly set JAAᵢ and the training geometric set JGAᵢ of each training set JEᵢ.

According to an embodiment example, the correlation search can be done using a least-squares method. It can consist of establishing an assumed polynomial relationship between the sets JAAᵢ and JGAᵢ, for each JEᵢ. Then the least-squares method makes it possible to find the best set of polynomial coefficients that minimizes the error between the outputs calculated by the polynomials obtained and the JGAᵢS.

According to another aspect of the present invention, a device is proposed, for geometric characterization of a target optical objective to be manufactured by stacking several optical elements, said device comprising:
at least one means for determining a set, called assembly set, comprising, for at least one optical element, a set, called individual set, comprising at least one characteristic parameter of said optical element; and
a geometric characterization model trained beforehand with a database, called training database, of training sets constituted with optical objectives with architecture identical to that of said target objective in order to provide, as a function of said assembly set, a data set, called estimated geometric set, comprising data relating to at least one geometric parameter of at least one optical interface of said stack.

The characterization device can optionally comprise any combination of at least one of the characteristics described above with reference to the geometric characterization method according to the invention, which for the sake of brevity are not repeated here in detail.

In particular, the characterization model can be integrated in a computer processing module, such as a processor, a chip, a computer, a tablet, a server, etc., whether dedicated or not.

According to another aspect of the present invention, a method is proposed for the manufacture of a batch of optical objectives including a second manufacture phase comprising at least one iteration of a step of manufacture of an optical objective of said batch comprising the following operations:
determining an assembly set for said optical objective, based on individual sets for each of the optical elements of said optical objective, and
characterizing said objective by the characterization method according to the invention.

At least one, and in particular each, estimated geometric set value obtained can be compared with at least one geometric value, or with a range of geometric values, in order to determine if the estimated quality of the optical objective is satisfactory.

If the estimated quality of the optical objective is satisfactory, then the optical objective can be manufactured.

If the estimated quality of the optical objective is not satisfactory, then the optical objective can be subjected to at least one other test, or not be manufactured.

Alternatively or in addition, if the estimated quality of the optical objective is not satisfactory, then the optical objective can be reworked to improve the estimated quality thereof. For example, at least one optical element of the optical objective can be repositioned (for example be pivoted according to an axis of rotation), or replaced by another optical element.

Thus, it is possible to validate or not an assembly of optical elements forming an objective even before producing said optical assembly, or even before beginning to manufacture said optical objective. This makes it possible to increase the efficiency of the development of the manufacturing methods, by virtue of the deduced information on the optical components, and of the production of optical objectives implementing these methods by virtue of the prediction data obtained well before the total completion of the objective, thus making it possible, among other things, to reduce the losses both of the optical components which can be directed towards favourable assemblies and objectives.

The variation of at least one item of data of the geometric set, or also the estimated quality deduced based on the estimated geometric set, can be monitored over time. This variation can be used to monitor the manufacturing of the objectives of one and the same batch. For example, when the variation shows a deviation, or a reduction, of the functional quality of the optical objectives of the batch that is too significant, an alert can be generated so that the manufacturing method can be readjusted.

Advantageously, the method of manufacture according to the invention can comprise a first manufacture phase, prior to the second manufacture phase, comprising at least one iteration of a step of manufacture of an optical objective of said batch comprising the following operations:
determining an assembly set for said optical objective, based on individual sets of the optical elements of said optical objective, and
stacking the optical elements forming said optical objective,
measuring a geometric set on said optical objective,
storing, in a training database, a training set formed by:
   said assembly set, and
   said measured geometric set.

This first manufacture phase makes it possible to constitute a training database for training the geometric characterization model used during the second manufacture phase.

### DESCRIPTION OF THE FIGURES AND EMBODIMENTS

Other advantages and characteristics will become apparent on examining the detailed description of embodiments that are in no way limitative, and from the attached drawings, in which:

FIG. 1 is a diagrammatic representation of a non-limitative embodiment example of an optical element capable of being used to manufacture an optical objective;

FIG. 2 is a diagrammatic representation of a non-limitative embodiment example of an optical objective capable of being characterized by the present invention;

FIGS. 3a to 3f are diagrammatic representations of a non-limitative embodiment example of optical interferometry measurement capable of being implemented in the present invention;

FIG. 4 is a diagrammatic representation of a non-limitative embodiment example of a method according to the invention for geometric characterization of an optical objective;

FIG. 5 is a diagrammatic representation of a non-limitative embodiment example of a device according to the invention for geometric characterization of an optical objective;

FIG. 6 is a diagrammatic representation of a non-limitative embodiment example of a training phase capable of being used in the present invention for training a geometric characterization model; and

FIG. 7 is a diagrammatic representation of a non-limitative embodiment example of a method according to the invention for the manufacture of an optical objective.

It is well understood that the embodiments that will be described hereinafter are in no way limitative. Variants of the invention can be envisaged in particular comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In particular, all the variants and all the embodiments described can be combined together if there is no objection to this combination from a technical point of view.

In the figures and in the description hereinafter, elements common to several figures retain the same reference.

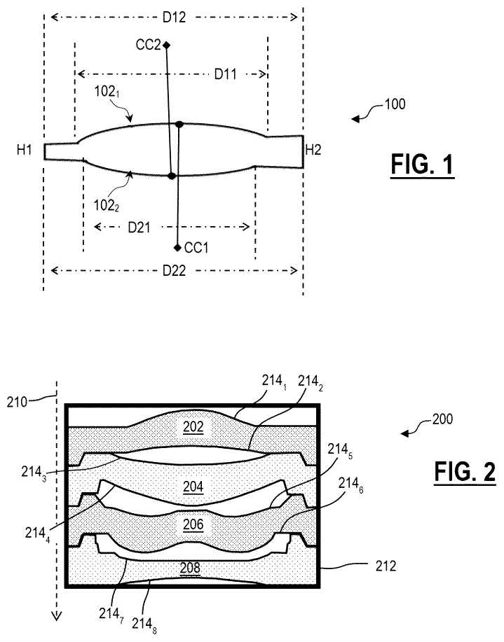

FIG. 1 is a diagrammatic representation of a non-limitative embodiment example of an optical element capable of being used to manufacture an optical objective.

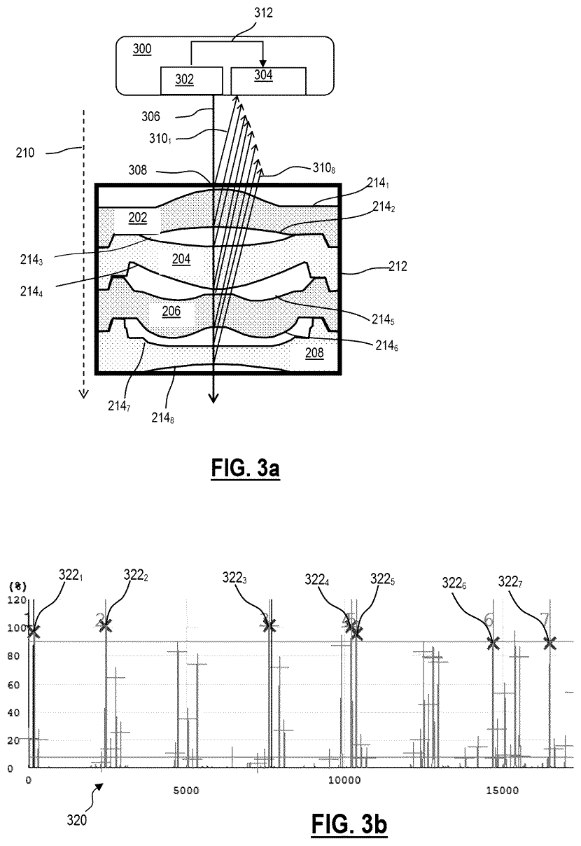

The optical element 100 of FIG. 1 can be used with at least one other optical element to manufacture an optical objective. An optical objective example, given by way of non-limitative example will be described with reference to FIG. 2.

The optical element 100 can be a lens, a beam splitter, etc.

Hereinafter, and without loss of generality, the optical element is considered to be a lens.

The optical lens 100 can for example be manufactured by injection moulding. An injection-moulding method generally follows the following succession of steps:
injecting the polymer and filling the mould,
pressurizing,
maintaining the pressure,
cooling, and
demoulding.

The methods for manufacturing lenses by injection, although common, can fluctuate and generate errors on the characteristic parameters of the lenses.

The lens 100 can be characterized by a set of parameters, called individual set JI.

The individual set JI can comprise at least one parameter relating to the process of manufacturing the lens, called manufacturing parameter. The individual set can comprise any combination of at least one of the following manufacturing parameters:
a moulding temperature, denoted TM;
a moulding pressure, denoted PM;
a moulding duration, denoted DM;
a polymer used for the moulding, denoted POM.

The values of these parameters are generally determined by the lens manufacturer. They can either be known as item of input data of the manufacturing process, or measured during the manufacture of the lens.

Moreover, the lens 100 has a given geometric shape. It includes two interfaces 102₁ and 102₂, each also having a given geometric shape themselves. Thus, the lens 100 has a shape which is characterized by at least one geometric parameter relating to the shape of the lens. The individual set JI can comprise, alternatively or in addition, any combination of at least one of the following geometric parameters:
a geometric shape of each of the optical interfaces 102₁ and 102₂;
a centre of curvature, denoted CC1 and CC2, of each of the optical interfaces 102₁ and 102₂;
a position of an apex, denoted A1 and A2, of each of the optical interfaces 102₁ and 102₂;
at least one thickness, denoted H1 and H2, of the lens 100 along its periphery;
an internal diameter, respectively D11 and D21, and/or an external diameter, respectively D12 and D22, of each of the interfaces 102₁ and 102₂;
a concentricity or an eccentricity value of the interfaces 102₁ and 102₂
a surface roughness of each of the optical interfaces 102₁ and 102₂;
etc.

The value of at least one geometric parameter can be provided by the manufacturer. Alternatively, or in addition, the value of at least one geometric parameter can be measured for example by optical or mechanical profilometry. Alternatively, or in addition, the value of at least one geometric parameter can be determined by simulation, based on a digital modelling of the lens 100. Alternatively, or in addition, the value of at least one geometric parameter can be measured for example by optical interferometry.

In addition, the lens 100 has optical characteristics since it is an optical element. It is therefore characterized by at least one optical parameter. Thus, the individual set JI can comprise, alternatively or in addition, at least one of the following optical parameters:
a refractive index, denoted I1 and I2, of each of the optical interfaces 102₁ and 102₂;
an Abbe number, denoted Ab,
etc.

The value of at least one optical parameter can be provided by the manufacturer. Alternatively, or in addition, the value of at least one optical parameter can be determined for example by optical measurement.

Thus, according to a non-limitative embodiment example, an individual set JI of a lens can be written:

JI={TM,PM,DM,PO; CC1,CC2,A1,A2,H1,H2,D11,D12,D21,D22; I1,I2,Ab}

Generally, the individual set can comprise M1 parameters with M1≥1 and preferably M1≥2.

This individual set of a lens can be used, with the individual set of at least one other optical element of an optical objective to form a set, called assembly set, denoted JA. If the optical objective comprises N optical elements, then the assembly set JA can comprise N×M1 parameters and can correspond to a matrix including N rows and M1 columns.

Of course, the individual sets JI of at least two optical elements can comprise one and the same number of parameters, or different numbers of parameters.

FIG. 2 is a diagrammatic representation of a non-limitative embodiment example of an optical objective capable of being characterized by the present invention.

An optical objective has the function of focusing an image of a scene in an image plane, generally constituted by a CMOS camera (called “CMOS imager system” giving the acronym CIS). Such an optical objective is generally constituted by a stack of optical elements comprising any combination of optical elements such as lenses, spacer and opacification rings, etc.

During the manufacture of the optical objective, each optical element of said objective is selected individually and stacked with the other optical elements in an assembly barrel, following a given order. The stack and barrel are then firmly fixed together by known techniques, for example by bonding.

In FIG. 2, and by way of non-limitative example only, the optical objective 200 comprises four lenses 202-208 stacked in a stacking direction 210, also called axis Z, in a barrel 212. At least two of the lenses 202-208 can be separated from one another by a void space, called “air gap”, or by a spacing sleeve or ring, also called “spacer”.

At least one of the lenses 202-208 can for example be the lens 100 of FIG. 1.

Each of the lenses 202-208 includes two interfaces, namely an interface called upstream, and an interface called downstream, in the stacking direction 210. Thus, the lens 202 has an upstream interface 214₁ and a downstream interface 214₂, the lens 204 has an upstream interface 2143 and a downstream interface 214₄, the lens 206 has an upstream interface 214₅ and a downstream interface 214₆ and the lens 208 has an upstream interface 214₇ and a downstream interface 214₈.

Thus, for the optical objective 200 of FIG. 2, the assembly set JA can comprise an individual set, denoted respectively JI₁-JI₄, for each of the optical elements 202-208, such that

JA={JI₁;JI₂; JI₃; JI₄}

The assembly set JA can be determined even before stacking the lenses of the optical objective 200, as soon as the optical elements composing the optical objective are known. In certain embodiments, the assembly set can be determined at the moment of design of each optical element composing the optical objective. It is thus possible to adjust each optical element at the moment of its design or at the moment of its manufacture with a view to optimizing the quality of the optical objective.

Moreover, for the optical objective 200, and generally for any optical objective comprising a stack of optical elements, it is possible to determine a data set, called geometric set, denoted JG hereinafter, comprising data relating to at least one geometric parameter of at least one, and in particular each, optical interface 214₁-214₈ of said stack.

Such a geometric set JG can comprise data relating to any one of the following geometric parameters:
at least one position value of at least one interface 214₁-214₈, or at least one optical element 202-208 of the objective 200;
at least one thickness value of an optical element 202-208 of the objective 200;
at least one decentration value of at least one interface 214₁-214₈, or at least one optical element 202-208, with respect to the axis Z, or relative to a centre position of another interface, in the plane X-Y; or
at least one inclination value of at least one interface 214₁-214₈, or at least one optical element 202-208, with respect to the axis Z, or relative to the inclination of another interface;
at least one topography or shape profile value of at least one optical interface 214₁-214₈.

Generally, the geometric set can comprise for each optical interface of the optical objective M2 geometric parameters with M2≥1 and preferably M2≥2. If the optical objective comprises N optical elements, then the assembly set JG can comprise 2N×M2 parameters and can correspond to a matrix including 2N rows and M2 columns. Of course, the assembly set can comprise one and the same number of geometric parameters for at least two optical interfaces, or different numbers of geometric parameters for at least two optical interfaces.

The geometric set JG can directly comprise the values of the geometric parameters. These values can be measured, conventionally, by optical interferometry or by confocal measurement(s), preferably from one side or one face of the optical objective 200, so as to avoid turning it.

Alternatively, the geometric set JG can comprise raw measurement data, such as for example optical interferometry measurement data or confocal measurement data.

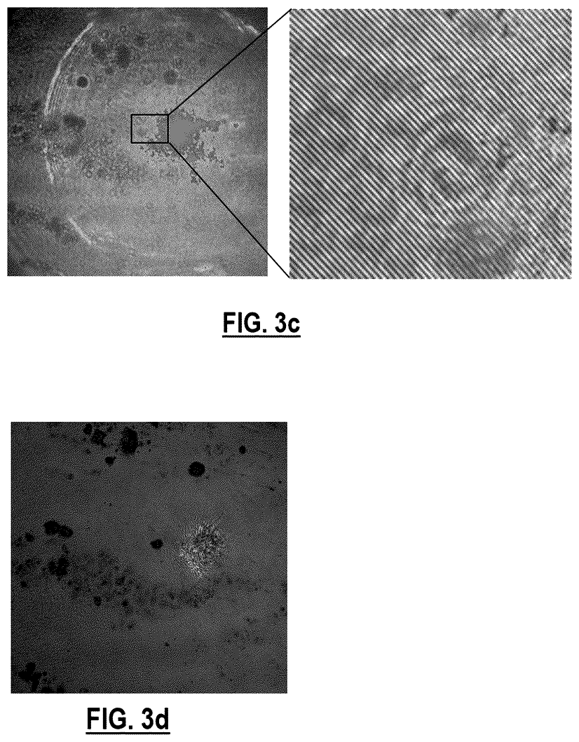

FIG. 3a is a diagrammatic representation of a non-limitative embodiment example of an optical interferometry measurement capable of being implemented in the present invention.

The optical interferometry measurement is performed by an optical interferometry appliance, or interferometric appliance, 300, shown in a highly diagrammatic way, in FIG. 3a. The appliance 300 comprises a light source 302 and an interferometry sensor 304. The source 302 emits, in the direction of stacking of optical elements, a beam 306 of coherent light, called measurement beam, at a measurement point, or according to a field of view 308, in the plane X-Y, perpendicular to the direction 210. The measurement beam 306 then travels through the stack of optical elements, in particular in the axis Z 210, and passes through each optical interface 214; in turn. At each optical interface 214i, a part 310; of the measurement beam 306 is reflected, such that:
a beam 3101 is reflected by the interface 214₁,
and so on and so forth
a beam 3108 is reflected by the interface 214₈.

Each reflected beam 310; of the measurement beam 306 is then captured by the sensor 304 also optically connected to the emission source 302, and will produce an interference signal when this reflected beam 310; and a reference beam 312, also originating from the light source 302, recombine on the sensor 304, the difference in the paths travelled by the two respective beams being less than the coherence length of the emission source 302. In particular, for each reflected beam 310; the sensor 304 provides an interference ray, called main ray, or an interference image, according to the illumination and detection modes implemented, at an optical distance corresponding to the position of the interface with respect to the emission source 302, or any other predetermined reference. Of course, apart from the beam 3101 reflected by the first interface 214₁ encountered by the measurement beam 306, a part of each of the other reflected beams 3102-3108 can itself be reflected in the other direction on passing through a preceding interface, which can generate multiple reflection optical beams (not shown) captured by the sensor 304. These multiple reflection beams generate interference rays, called secondary rays, or secondary images, generally of lower amplitude.

The optical interferometry measurements can be performed with a measurement beam from an interferometric sensor illuminated by a low-coherence light source. To this end, the optical interferometry appliance has available positioning means for relatively positioning a coherence area of the interferometric sensor 304 at the level of the interface to be measured. The interface to be measured can be a buried interface, i.e. one of the interfaces inside the optical element. In order to reach such a buried interface, the measurement beam must therefore pass through other interfaces of the optical objective. The interferometric device makes it possible to detect an interference signal selectively for each interface at the level of which the coherence area is positioned, i.e. for each surface located in the coherence area, since the coherence length of the light source is adjusted so as to be shorter than a minimum optical distance between two adjacent optical interfaces of the optical objective. Thus, preferably, for each measurement, a single interface is located in the coherence area.

The interference measurements can be performed according to a field of view determined by the measurement means of the appliance. The measurements can thus be carried out either full-field, or by scanning the field of view.

Digital processing means can be configured to produce, based on the interference signal, an item of shape information, or a geometric parameter, of the interface measured according to the field of view.

Examples of interferometric appliances capable of being utilized in the context of the present invention are, for example, described in the document WO2020/245511 A1.

FIG. 3b gives a partial diagrammatic representation of raw measurement data obtained for an optical interferometry measurement, such as that described with reference to FIG. 3a.

In this implementation example, a measurement point illumination is used, and the coherence area is displaced along the optical axis Z 210 by virtue of displacement means.

Thus, as described with reference to FIG. 3a, each interference measurement provides raw data 320. The raw data 320 comprise main rays 322ᵢ, each main ray corresponding to an optical interface. For example, a main ray 322₁ is obtained for the interface 214₁, a main ray 322₂ for the interface 214₂, etc. (the interface 214₈ does not appear in the example shown in FIG. 3b).

The raw data 320 also comprise secondary rays corresponding to multiple reflections, and associated with the interfaces 214₂-214₈.

The optical position of each ray is given on the x-axis and the normalized amplitude of each ray is given on the y-axis.

FIGS. 3c-3f are partial diagrammatic representations of another example of raw measurement data obtained for an optical interferometry measurement, such as that described with reference to FIG. 3a.

In the example shown in FIGS. 3c-3f, an illumination according to a full-field mode is used and the coherence area has been positioned so as to measure a buried lens surface. FIG. 3c shows the interference signal detected during a digital holography microscopy (DHM) measurement. FIGS. 3d and 3e show respectively the amplitude and phase images (in this folded example) calculated based on the interference signal. FIG. 3f is an image of the topography of the surface of a buried lens obtained based on the phase information.

As indicated above, according to embodiments, the geometric set can comprise raw measurement data, partially or wholly, namely:
in an illumination configuration according to a measurement point, for example:
   the position, and optionally the amplitude, of each main ray, or
   the position, and optionally the amplitude, of each ray, (main or secondary);
in an illumination configuration according to a field of view, for example:
   the interference image detected by the interferometry sensor 204,”
   the amplitude image associated with the interference image and/or the phase image associated with the interference image, or
   the topography image associated with the interference image.

According to embodiments, the geometric set can comprise, not raw measurement data obtained by an optical interferometry measurement, but geometric parameter values relating to the optical interfaces of the objective, namely:
the position, along the axis Z, of each interface 214; or of each optical element 302-308. These distance values can be obtained based on the raw data from a single interferometric measurement. In this case, the geometric set comprises a distance value per interface, respectively per optical element;
the decentration with respect to the axis Z or relative to other interfaces in the plane X-Y, of each interface 214; or of each optical element 202-208. These decentration values can be deduced based on an interference image associated with an optical interface, for example. In this case, the geometric set comprises two (signed) distance values (one along the axis X and the other along the axis Y) for each interface, respectively optical element;
the inclination with respect to the axis Z or to the inclination of other optical interfaces of each optical interface 214; or of each optical element 202-208. These inclination values can be deduced based on several interferometric measurements performed at different measurement points, in particular in a peripheral area of the optical objective. In this case, the geometric set comprises two angle values (one with respect to the axis X and the other with respect to the axis Y) for each interface, respectively optical element.

With reference to FIG. 3a, it is understood that the measurement of a geometric set for an optical objective can be time-consuming and require the use of a bulky optical interferometry appliance. In addition, the measurement of a geometric set on an optical objective makes it necessary to temporarily stop the manufacture of said objective, for the time it takes to carry out the measurement, which constitutes a slow-down, or perhaps a loss of time, in the production of an optical objective.

The present invention proposes to determine, for an optical objective, called target optical objective, a geometric set by estimation. To this end, an assembly set, as described with reference to FIGS. 1 and 2, is given at input of a geometric characterization model trained beforehand which, at output, provides an estimated geometric set, denoted JGE.

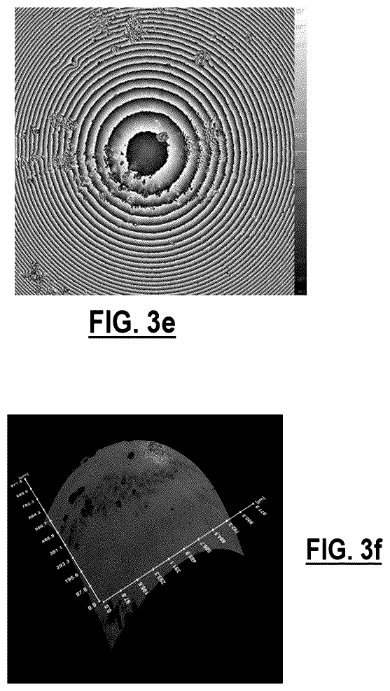

FIG. 4 is a diagrammatic representation of a non-limitative embodiment example of a method according to the invention for geometric characterization of an optical objective.

The method 400 of FIG. 4 can be used for geometric characterization of an optical objective comprising several lenses, such as for example the optical objective 200 of FIG. 2, without being limited thereto.

The method 400 comprises a phase 402 of characterization of an optical objective, called target objective, during the manufacture thereof.

The characterization phase 402 comprises a step 404 of determining an assembly set based on the individual set, JI, of each optical element composing the stack of optical elements of the target optical objective, as described above. The individual set JI of each optical element can comprise one or more parameters relating to said optical element.

For each optical element, at least one parameter can be determined as described above either based on items of information provided by the manufacturer, or by measurement, or by simulation.

This step 404 provides, for the stack of optical elements of the optical objective, an assembly set JA comprising at least one characteristic parameter of at least one, and in particular each, optical element of said stack.

The characterization phase 402 comprises a step 404 during which the assembly set JA determined for the target optical objective is provided to a geometric characterization model trained beforehand. In response, the geometric characterization model provides an estimated geometric set JGE for said target objective.

The JGE can comprise one or more values. Preferably, the JGE comprises several values.

The geometric set JGE can comprise either geometric parameter values of at least one, and in particular each, optical interface of the stack, such as for example the geometric parameters described with reference to FIGS. 3a-3f (alignment, decentration, etc.).

The estimated geometric set JGE can comprise estimated raw values of optical interferometry measurements, or confocal measurements, relating to at least one, and in particular each, optical interface of the stack, such as for example those described with reference to FIGS. 3a-3f (interference signal, interference rays, etc.).

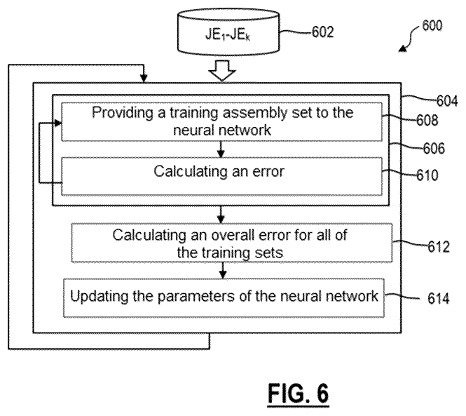

Optionally, the method 400 can comprise a phase 420 of training the geometric characterization model with a training database comprising several training sets obtained based on objectives with architecture identical to that of the target objective, either by measurement or by simulation. A non-limitative training phase example is described below with reference to FIG. 6.

Thus, the method 400 allows a geometric characterization of the target optical objective by estimation with a geometric characterization model trained beforehand, without performing measurements on the stack of optical elements of the optical objective, or even before beginning to manufacture said optical objective. Thus, it is possible to have indicators relating to the quality of the optical objective before manufacturing it and deciding to manufacture said objective or not. For example, it is possible to avoid manufacturing an optical objective the estimated quality of which is not satisfactory.

In addition, the method 400 allows design of experiments (DOE) to be implemented to analyse the parameters of the components, for them to be classified according to the results of the geometric characterization obtained in order to, for example, reject certain components very early in the manufacture, to be able to match classes between different optical components or to apply inherent corrections to this class (modification of the spacing, rotation of the lens, etc.).

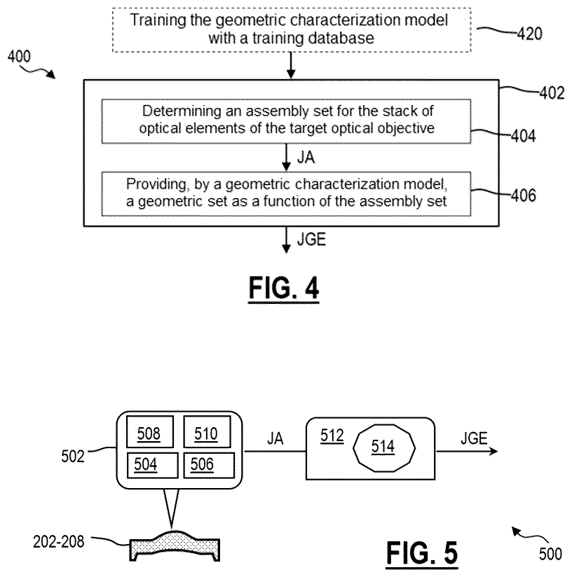

FIG. 5 is a diagrammatic representation of a non-limitative embodiment example of a device according to the invention for geometric characterization of an optical objective.

The device 500 can be used to characterize at least one optical objective, in particular before or during the manufacture thereof, such as for example the optical objective 200 in FIG. 2.

The device 500 comprises a module 502 for determining an assembly set, based on the characteristics of each optical element composing the target optical objective.

The module 502 can comprise:
an optical, or mechanical, profilometry appliance 504; and/or
an optical interferometry appliance 506 in point mode or in full-field mode, such as for example the optical interferometry appliance 300 in FIG. 3a
   for measuring at least one geometric parameter of at least one, in particular each, optical element provided to compose the optical objective.

The module 502 can comprise, alternatively or in addition, a computerized unit 508, such as a processor or a calculator, configured to:
read in a database characteristic parameter values of each optical element provided to compose the optical objective; and/or
calculate, by simulation and based on a modelling of at least one optical element, at least one characteristic of said optical element.

The module 502 can comprise, alternatively or in addition, a user interface 510 allowing an operator to manually enter a value of at least one characteristic parameter of at least one optical element provided to compose the optical objective.

The module 502 provides an assembly set JA for the stack of optical elements provided to compose the optical objective.

The device 500 also comprises a characterization module 512 executing a geometric characterization model 514 taking at input the assembly set JA provided by the module 502 and providing at output an estimated geometric set JGE. The geometric characterization model 514 can be a computerized program or application and be presented in the form of:
a neural network, in particular a regression neural network, and even more particularly a deep learning CNN neural network, or
a polynomial linear regression model,
a Gaussian equation, obtained by a least squares method,
a statistical analysis method,
etc.

The geometric characterization module 512 can be any calculation module or any computerized module executing the characterization model 514, such as a server, a computer, a tablet, a processor, a calculator, an electronic chip, etc.

FIG. 6 is a diagrammatic representation of a non-limitative embodiment example of a training phase capable of being used in the present invention for training a geometric characterization model.

The training phase 600 in FIG. 6 can be used to train the geometric characterization model used in the method according to the invention for geometric characterization of an optical objective, and for example the method 400 in FIG. 4, when the training model is a neural network.

The neural network used can be a CNN neural network (for “convolutional neural network”). It is important to note that the number of layers of the neural network is a function of the number of data items in the assembly set provided at input of said neural network, and of the number of data in the geometric set desired at output.

The training phase 600 is performed with a training database 602 comprising numerous sets of training data, denoted JE₁-JEₖ. Each training set

JEᵢ comprises, for a training optical objective:
at least one training assembly set, JAAᵢ; and
a training geometric set, JGAᵢ.

The training optical objective has an architecture identical to that of the target optical objective which it is desired to characterize by the geometric characterization model.

Each training assembly set JAAᵢ can be obtained for example as described above with reference to FIGS. 1 and 2, i.e. by determining an individual set for each optical element composing the training optical objective then the training assembly set based on said individual sets.

Each training geometric set JGAᵢ can be obtained for example by measurement on the training optical objective, for example by optical interferometry as described above with reference to FIGS. 3a-3f, or by simulation based on a digital modelling of the training optical objective.

The training phase 600 comprises a training step 604.

The training step 604 comprises a test step 606.

The test step 606 comprises a step 608 during which a training assembly set, for example JAA₁, of a training set, for example JE₁, is given at input of the neural network. The neural network gives at output an estimated training geometric set, denoted JGA₁e.

During a step 610 of the test step 606, an error, E₁, can be calculated between the set JGAᵢ^{e} and the set JGA₁. The calculated error E₁ can for example be a Euclidean distance or a cosine distance between the set JGA₁^{e} and the set JGA₁.

The test step 606 can be reiterated for each training set JE₁-JEₖ, so that k error values E₁-Eₖ are obtained associated respectively with each training set JE₁-JEₖ.

The training step 604 can then comprise a step 612 of calculating an overall error, EG, for all of the training sets JE₁-JEₖ, for example by adding the k errors JE₁-JEₖ obtained.

The training step 604 can then comprise a feedback step 614, during which the coefficients, or weightings, of the CNN neural network can be updated, for example by an error gradient retro-propagation algorithm.

The training step 604 can be repeated several times until the overall error EG no longer varies during several, for example 5, successive iterations. When this is the case, the CNN neural network can be considered sufficiently trained and the training phase can be ended.

Alternatively, or in addition to what has just been described, it is possible to use a first part of the training database 602, for example JE₁-JEᵢ, for training the neural network and a second part of the training database 602, for example JEᵢ₊₁-JEₖ, to validate the training of the neural network. If the outputs of the neural network obtained are sufficiently close to the expected values, the learning can be considered acceptable. Otherwise, further training sets can be presented, or else the topology of the network is modified (number of layers, number of neurones per layer, etc.) until a satisfactory learning is obtained.

Of course, the geometric characterization model is not limited to a neural network.

According to an alternative, the geometric characterization model can comprise, or can be, a correlation search method, for example by a regression method, between the training assembly set JAAᵢ and the training geometric set JGAᵢ of each training set JEᵢ.

According to an embodiment example, the correlation search can take place using a least-squares method. It can consist of establishing an assumed polynomial relationship between the sets JAAᵢ and JGAᵢ, for each JEᵢ. Then the least-squares method makes it possible to find the best set of polynomial coefficients that minimizes the error between the outputs calculated by the polynomials obtained and the JGAᵢs.

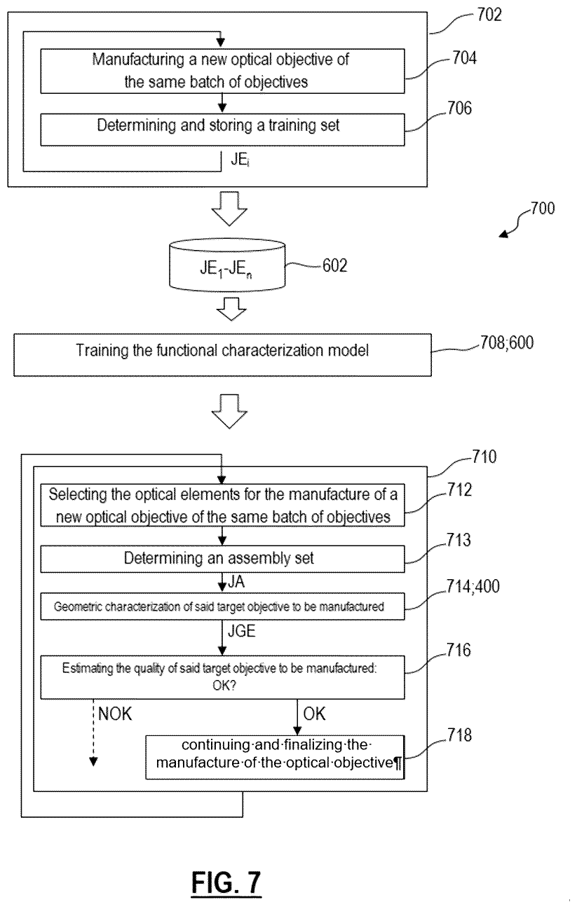

FIG. 7 is a diagrammatic representation of a non-limitative embodiment example of a method according to the invention for the manufacture of optical objectives.

The method 700 can comprise a first phase 702 of manufacture during which a first part of a batch of objectives is manufactured. This first part comprises numerous optical objectives. During this phase 702 an optical objective is manufactured during a step 704, then a training set JE is determined and stored during a step 706, so as to constitute a training database, such as for example the training database 602.

Then, during a step 708, the geometric characterization model is trained with the training database, for example by implementing the training phase 600 in FIG. 6.

The method 700 can then comprise a second phase 710 of manufacture during which the remaining objectives of the batch are manufactured.

This phase 710 comprises, for each optical objective, a step 712 of selecting the optical elements which will constitute the optical objective.

During a step 713, an assembly set is determined for the stack of selected optical elements.

During a step 714, preferably carried out before stacking of the optical elements, the optical objective to be manufactured is characterized, using the geometric characterization model obtained in step 708, by the method according to the invention of functional characterization, and in particular by the method 400 in FIG. 4, to obtain an estimated geometric set for the target optical objective to be manufactured.

Then, during a step 716, at least one, and in particular each, estimated geometric set value obtained can be compared with at least one range of geometric values, in order to determine if the expected quality of the optical objective is satisfactory.

If the estimated geometric set shows a satisfactory quality of the optical objective, the manufacture of the optical objective can be begun or continued during a step 718.

If the estimated geometric set shows an unsatisfactory quality, then the manufacture of the optical objective can be cancelled. Alternatively, if the estimated geometric set shows an unsatisfactory quality, then the composition of the optical objective can be reworked. For example, at least one optical element of the optical objective can be replaced.

Of course, the invention is not limited to the examples that have just been described.

1. A method for geometric characterization of a target optical objective to be manufactured by stacking several optical elements, said method comprising a characterization phase comprising the following steps:
determining a set, called assembly set, comprising, for at least one optical element, a set, called individual set, comprising at least one parameter characteristic of said optical element; and
providing, as a function of said assembly set, a data set, called estimated geometric set, comprising data relating to at least one geometric parameter of at least one optical interface of said stack, by a geometric characterization model trained beforehand with a database, called training database, of training sets constituted with optical objectives with architecture identical to that of said target objective.

2. The method according to claim 1, characterized in that at least one individual set of an optical element comprises any combination of at least one of the following parameters:
at least one optical parameter of said optical element;
at least one geometric parameter of said optical element; and
at least one manufacturing parameter of said optical element.

3. The method according to claim 1, characterized in that at least one parameter of an optical element is:
provided by a supplier of said optical element,
measured by a measurement device, or
calculated based on a digital modelling of said optical element.

4. The method according to claim 1, characterized in that the estimated geometric set comprises the estimated value of at least one geometric parameter of an optical interface of the target objective.

5. The method according to claim 1, characterized in that the estimated geometric set comprises estimated data of a part, or all, of the raw optical measurement values obtained from the stack of optical elements of said target optical objective.

6. The method according to claim 1, characterized in that at least one training set comprises:
at least one assembly set, called training assembly set, obtained from an optical objective, called training optical objective, with architecture identical to the architecture of the target objective; and
at least one geometric set, called training geometric set, obtained from said training optical objective.

7. The method according to claim 1, characterized in that the training database comprises at least one training set obtained from a training objective forming part of one and the same batch of objectives as the target objective, during the manufacture of said batch of objectives.

8. The method according to claim 1, characterized in that the geometric characterization model comprises:
a neural network, in particular a regression neural network, and even more particularly a deep learning CNN neural network,
a polynomial linear regression model,
a Gaussian equation, obtained by a least squares method, or
a statistical analysis method.

9. The method according to claim 1, characterized in that it comprises a phase of training the geometric characterization model with the training database.

10. A device for geometric characterization of a target optical objective to be manufactured by stacking several optical elements said device comprising:
at least one means for determining a set, called assembly set, comprising, for at least one optical element, a set, called individual set, comprising at least one parameter characteristic of said optical element; and
a geometric characterization model trained beforehand with a database, called training database, of training sets constituted with optical objectives with architecture identical to that of said target objective to provide, as a function of said assembly set, a data set, called estimated geometric set, comprising data relating to at least one geometric parameter of at least one optical interface of said stack.

11. A method for the manufacture of a batch of optical objectives including a second manufacture phase comprising at least one iteration of a step of manufacture of an optical objective of said batch comprising the following operations:
determining an assembly set for said optical objective, based on individual sets for each of the optical elements of said optical objective, and
characterizing said objective by the characterization method according to claim 1.

12. The method according claim 11, characterized in that it also comprises a first manufacture phase, prior to the second manufacture phase, comprising several iterations of a step of manufacture of an optical objective from the batch of objectives comprising the following operations:
determining an assembly set for said optical objective, based on individual sets of the optical elements of said optical objective, and
stacking the optical elements forming said optical objective,
measuring a geometric set on said optical objective,
storing, in a training database, a training set formed by:
said assembly set, and
said measured geometric set.
